(19) United States
(12) Patent Application Publication
(10) Pub. No.: US 2026/0047018 A1
(43) Pub. Date: Feb. 12, 2026

(54) ELECTRONIC DEVICE CASING

(71) Applicant: PEGATRON CORPORATION, TAIPEI CITY (TW)

(72) Inventors: Ying-De Chen, TAIPEI CITY (TW); Wei-Min Lou, TAIPEI CITY (TW)

(21) Appl. No.: 19/243,325

(22) Filed: Jun. 19, 2025

(30) Foreign Application Priority Data
Aug. 7, 2024 (TW) 113129482

(51) Int. Cl. H05K 5/02; F16B 5/00; F16B 5/07; H05K 5/03; H05K 7/14

(52) U.S. Cl. CPC H05K 5/0221; F16B 5/0084; F16B 5/07; H05K 5/03; H05K 7/1487

(57) ABSTRACT

An electronic device casing includes a case body, a first cover plate, and a second cover plate. The case body has a pair of side plates. The first cover plate is assembled to the case body and includes a fastening member and a first hook member. The fastening member is movably engaged with the side plate, so that the first cover plate and the case body are in a locked or an unlocked state. The first and second cover plates jointly cover the case body. The second cover plate includes at least one second hook member. In the locked state, the second hook member is engaged with the first hook member to restrict displacement of the second cover plate relative to the case body. In the unlocked state, the first cover plate can drive the second cover plate to move relative to the case body.

### CROSS-REFERENCE TO RELATED PATENT APPLICATION

This application claims the benefit of priority to Taiwan Patent Application No. 113129482, filed on Aug. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic device casing, and more particularly to an electronic device casing having a removable cover plate.

### BACKGROUND OF THE DISCLOSURE

A conventional electronic device casing, such as a server chassis, typically has a two-piece top cover that covers the casing. Each top cover piece of such an electronic device casing has a locking mechanism that is locked to the case body.

However, certain problems exist in the conventional electronic device case body. Specifically, during the process of unlocking the two-piece top cover, top cover pieces need to be unlocked separately. In addition, the locking mechanisms occupy part of an internal space of the case body, and manufacturing cost is increased due to the configuration of the two separate locking mechanisms.

Therefore, how to improve the electronic device casing through improvements in structural design, so as to overcome the aforementioned problems, has become one of the important issues to be addressed in the related art.

### SUMMARY OF THE DISCLOSURE

In response to the above-referenced technical inadequacies, the present disclosure provides an electronic device casing. One of two-piece cover plates is provided with a locking mechanism, and the other cover plate does not need one. As such, an unlocking operation process can be more convenient, less internal space is occupied, and the cost can be reduced.

In order to solve the above-mentioned problems, one of the technical aspects adopted by the present disclosure is to provide an electronic device casing. The electronic device casing includes a case body, a first cover plate, and a second cover plate. The case body has a pair of side plates. The first cover plate is configured to be assembled to the case body. The first cover plate includes at least one fastening member and at least one first hook member. The at least one first hook member is located on one side of the first cover plate. The at least one fastening member is movably engaged with at least one of the side plates of the case body, so that the first cover plate and the case body are in a locked state or an unlocked state. The second cover plate is configured to be assembled to the case body. The second cover plate is adjacent to the first cover plate. The first cover plate and the second cover plate jointly cover the case body. The second cover plate includes at least one second hook member. When the first cover plate and the case body are in the locked state, the at least one second hook member is engaged with the at least one first hook member to restrict displacement of the second cover plate relative to the case body. When the first cover plate and the case body are in the unlocked state, the first cover plate is detachable from the case body in a direction away from the second cover plate, and the at least one first hook member is simultaneously driven to disengage from the at least one second hook member, so that the second cover plate is movable relative to the case body.

Therefore, in the electronic device casing provided by the present disclosure, when the first cover plate and the case body are in the locked state, through the at least one second hook member engaged with the at least one first hook member, the displacement of the second cover plate relative to the case body can be restricted. Accordingly, the fastening member can be omitted from the second cover plate in contrast to the conventional technology, thereby reducing the cost and not taking up the space below the second cover plate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is an exploded perspective view of an electronic device casing according to the present disclosure.

FIG. 2 is another exploded perspective view of the electronic device casing according to the present disclosure.

FIG. 3 is a partially exploded perspective view of the electronic device casing according to the present disclosure.

FIG. 4 is an assembled perspective view of the electronic device casing in a locked state according to the present disclosure.

FIG. 5 is a schematic cross-sectional view of FIG. 4 sectioned along line V-V.

FIG. 6 is a schematic cross-sectional view of FIG. 4 sectioned along line VI-VI.

FIG. 7 a partially assembled perspective view of the electronic device casing in the locked state according to the present disclosure.

FIG. 8 is a schematic cross-sectional view of FIG. 4 sectioned along line VIII-VIII.

FIG. 9 is a schematic cross-sectional view of FIG. 4 sectioned along line IX-IX.

FIG. 10 is a cross-sectional view of FIG. 8 in an unlocked state according to the present disclosure.

FIG. 11 is a side cross-sectional view of FIG. 4 in the locked state, sectioned along the line VI-VI, according to the present disclosure.

FIG. 12 is a side cross-sectional view of FIG. 11 in the unlocked state according to the present disclosure.

FIG. 13 is a side cross-sectional view of FIG. 5 in the unlocked state according to the present disclosure.

FIG. 14 is a side cross-sectional view of FIG. 6 in the unlocked state according to the present disclosure.

### DETAILED DESCRIPTION OF THE EXEMPLARY EMBODIMENTS

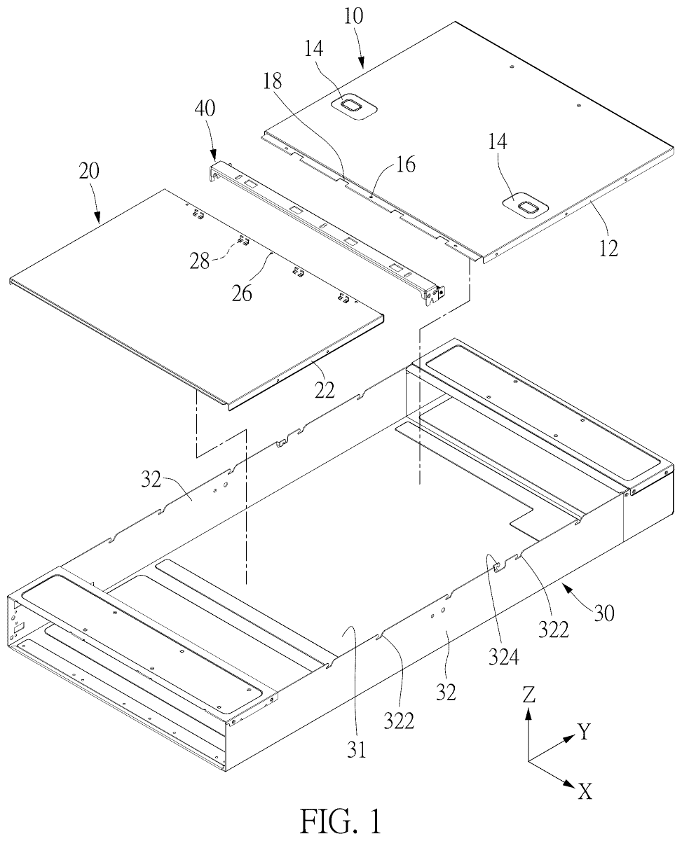

Referring to FIG. 1, an embodiment of the present disclosure provides an electronic device casing, which may be applied to a server, but the present disclosure is not limited thereto. The electronic device casing includes a first cover plate 10, a second cover plate 20, a case body 30, and a bridge member 40. The case body 30 may be formed by stamping metal plates. The case body 30 has a pair of side plates 32 and a base plate 31. The pair of side plates 32 are connected to two sides of the base plate 31. The second cover plate 20 is adjacent to the first cover plate 10. The first cover plate 10 and the second cover plate 20 jointly covers the case body 30.

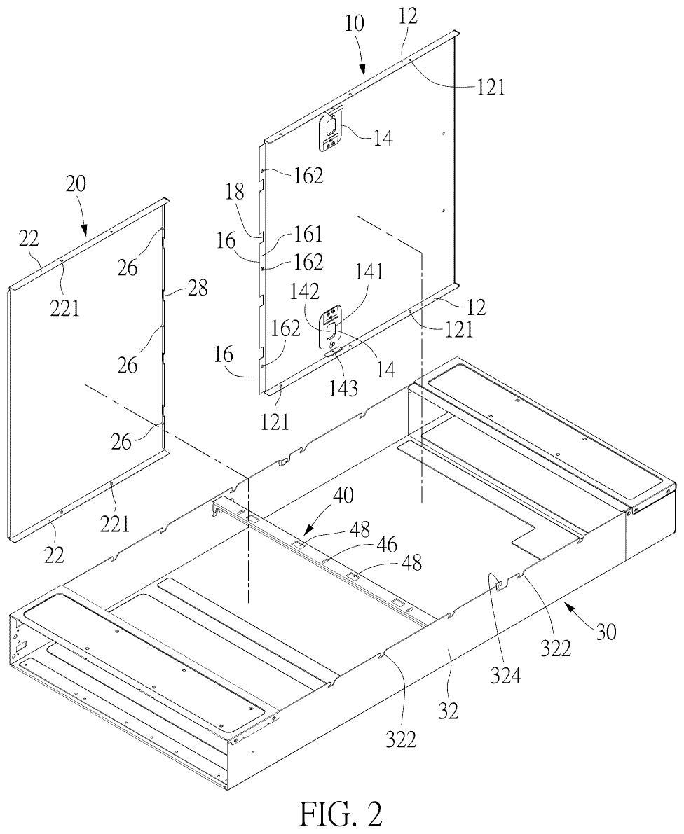

As shown in FIG. 2, two ends of the bridge member 40 are fixed to the pair of side plates 32, for example, being screwed into the case body 30 by screw bolts. The bridge member 40 is located below an adjoining area of the first cover plate 10 and the second cover plate 20. The bridge member 40 supports the first cover plate 10 and the second cover plate 20 and may restrict the displacement of the first cover plate 10 and the second cover plate 20.

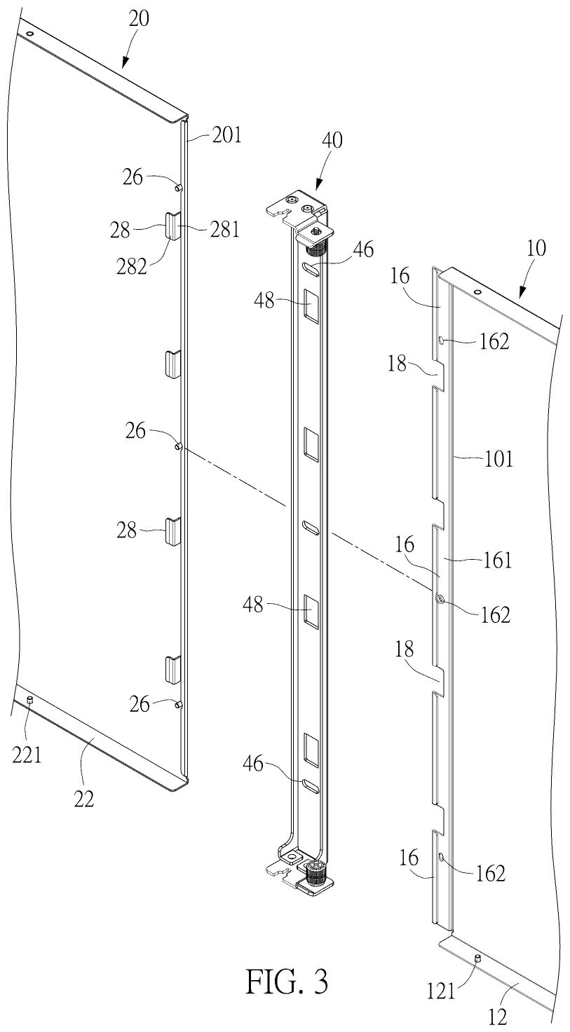

As shown in FIGS. 2 and 3, the first cover plate 10 is assembled to approximately a half upper opening of the case body 30. The first cover plate 10 may be formed by stamping a metal plate. The first cover plate 10 has a pair of fastening members 14 and a plurality of first hook members 16. The pair of fastening members 14 are movably engaged with the pair of side plates 32 of the case body 30, such that the first cover plate 10 and the case body 30 are in a locked state or an unlocked state. In this embodiment, the quantity of the fastening members 14 may be at least one. For example, two ends of one fastening member 14 extend to the pair of side plates 32. The plurality of first hook members 16 are located on one side of the first cover plate 10 (i.e., a side that is adjacent to the second cover plate 20), so as to be engaged with the second cover plate 20. The quantity of the first hook members 16 may be at least one.

The second cover plate 20 is assembled to the other half of the upper opening of the case body 30. The second cover plate 20 may be formed by stamping a metal plate. The second cover plate 20 has a plurality of second hook members 26. The first hook members 16 and the second hook members 26 are engaged, such that the second cover plate 20 can be latched to the first cover plate 10. The quantity of the second hook members 26 corresponds to that of the first hook members 16 and may be at least one.

In this embodiment, a key feature is that only the first cover plate 10 is equipped with the fastening members 14 while the second cover plate 20 does not require any fastening members. When the first cover plate 10 is locked to the case body 30 by engaging the first cover plate 10 with the second cover plate 20, the second cover plate 20 can be closed and fixed to the case body 30 in a synchronous manner.

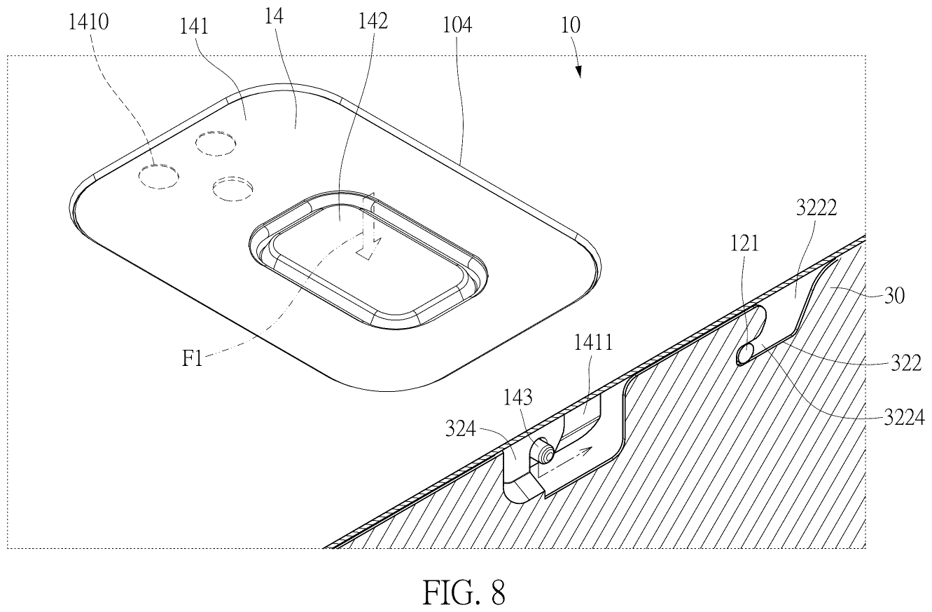

Reference is made to FIGS. 1 and 2 in cooperation with FIG. 8. FIG. 8 illustrates a cross-sectional view of the first cover plate 10 assembled to the case body 30, and both sides of the first cover plate 10 and the second cover plate 20 are slidably engageable with the pair of side plates 32. Each side plate 32 has a plurality of hook grooves 322 (as shown in FIG. 8). Each hook groove 322 has an upper notch 3222 and a lower notch 3224 and is substantially L-shaped. The upper notch 3222 extends downwards from a top edge of the side plate 32, and the lower notch 3224 extends horizontally in a direction from the first cover plate 10 toward the second cover plate 20 (i.e., the negative Y-axis direction in FIG. 1). A plurality of protruding first sliders 121 are disposed on and protrude from each of two sides of the first cover plate 10. A plurality of protruding second sliders 221 is disposed on and protrudes from each of two sides of the second cover plate 20. Specifically, the first cover plate 10 has a first side wall 12 on each side, and the first sliders 121 are disposed on an inner side of the first side wall 12. The first sliders 121 may be small cylindrical components secured to the first side wall 12 by riveting or screwing. Similarly, the second cover plate 20 has a second side wall 22 on each side, and the second sliders 221 are fixed to an inner side of the second side wall 22. The second sliders 221 may also be small cylindrical components fixed to the second side wall 22 by riveting or screwing.

The first sliders 121 and the second sliders 221 are correspondingly and slidably engaged with the hook grooves 322, thereby restricting the upward displacement of the first cover plate 10 and the second cover plate 20. In this embodiment, the first cover plate 10 and the second cover plate 20 slide in the same direction (i.e., along the Y-axis in FIG. 1) to detach from the case body 30. The second cover plate 20 is restricted by the hook grooves 322 from sliding backwards (i.e., away from the first cover plate 10). In other words, in order to slide away from the side plates 32, the second cover plate 20 needs to slide in a direction in which the first cover plate 10 is detached from the case body 30.

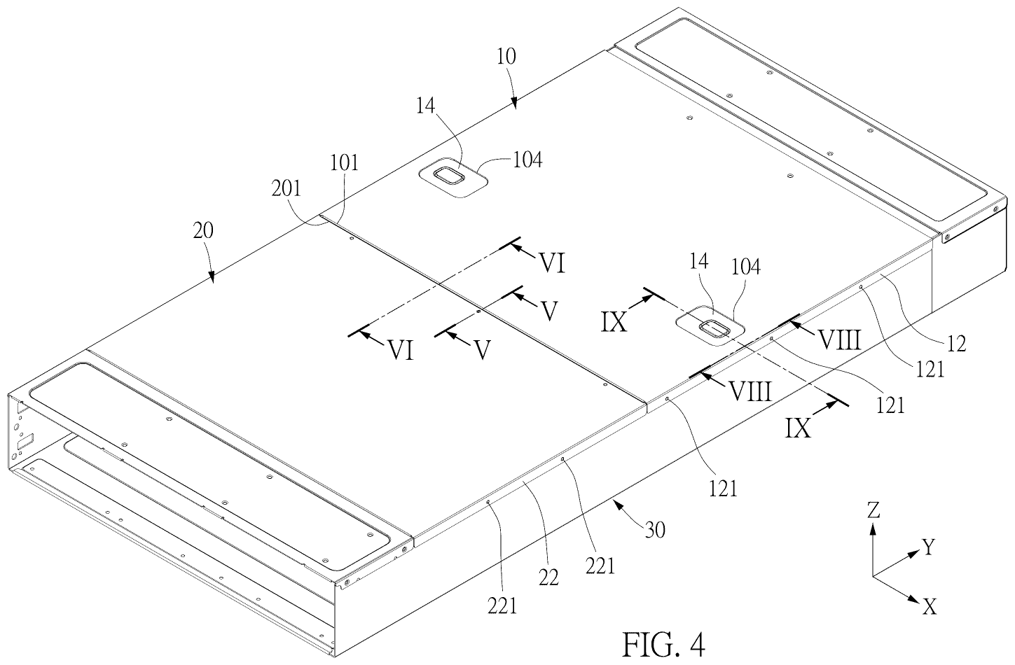

Referring to FIGS. 3 and 4, an example of a fastening approach for the first hook members 16 and the second hook members 26 is described below. The first cover plate 10 includes a first adjoining edge 101, the second cover plate 20 includes a second adjoining edge 201, and the first adjoining edge 101 and the second adjoining edge 201 face each other. As shown in FIG. 4, when the first cover plate 10 is in the locked state, the first adjoining edge 101 abuts the second adjoining edge 201.

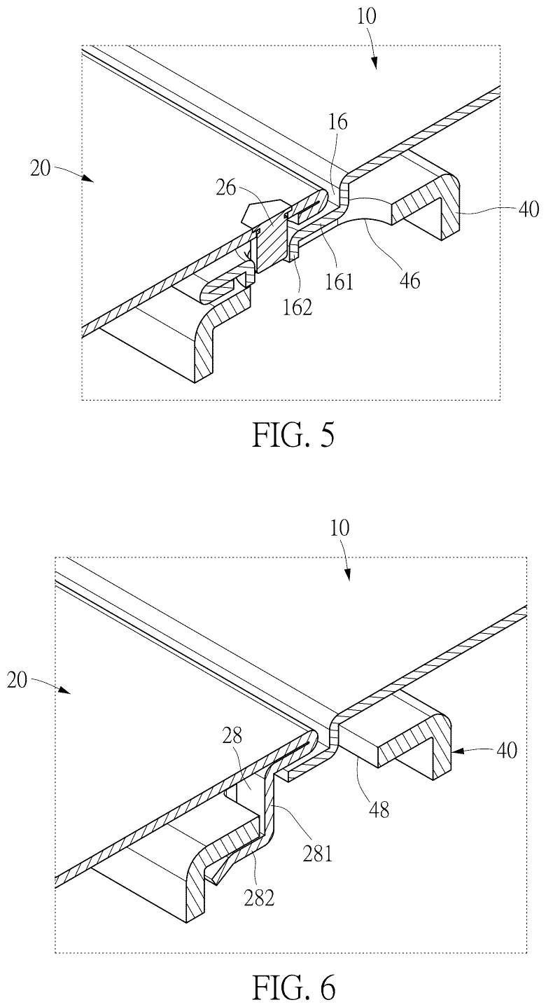

As shown in FIG. 3, the plurality of first hook members 16 of the first cover plate 10 are adjacent to the first adjoining edge 101. Each first hook member 16 includes an engagement plate 161 and a limiting aperture 162. The engagement plate 161 is bent downwards from the first adjoining edge 101 and extends to a bottom of the second cover plate 20. The limiting aperture 162 is formed on the engagement plate 161 and may, for example, be formed by stamping. The plurality of second hook members 26 of the second cover plate 20 is adjacent to the second adjoining edge 201. Each second hook member 26 is a columnar component fixed to the bottom surface of the second cover plate 20. In this embodiment, as shown in FIGS. 3 and 5, the bridge member 40 is provided with a plurality of relief holes 46 that correspond to the quantity and position of the second hook members 26.

### Locked State

Reference is made to FIGS. 4 and 5, FIG. 5 is a cross-sectional view of FIG. 4 sectioned along line V-V. When the first cover plate 10 and the case body 30 are in the locked state, the second hook members 26 (i.e., the columnar components) are inserted into the limiting apertures 162 of the first hook members 16. At this time, the second hook members 26 are engaged with the first hook members 16, such that the second hook members 26 are hooked by the first hook members 16 and therefore the displacement of the second cover plate 20 relative to the case body 30 is restricted, which prevents free movement along a longitudinal direction of the side plates 32 (i.e., the Y-axis direction in the figures). In this embodiment, the engagement between the second hook members 26 and the first hook members 16 is achieved by a cylindrical-post-and-aperture latching mechanism. However, the present disclosure is not limited thereto, and alternative fastening means, such as interlocking hook-shaped elements may be exploited.

In the present embodiment, when the first cover plate 10 and the case body 30 are in the locked state, the bridge member 40 not only supports the first cover plate 10 and the second cover plate 20, but also restricts the upward displacement of the first cover plate 10 and the second cover plate 20 (i.e., in the Z-direction as shown in FIGS. 1 and 4).

Specifically, as shown in FIGS. 3 and 6, the bridge member 40 has a plurality of stopping holes 48, and the second cover plate 20 further includes a plurality of limiting baffles 28. The limiting baffles 28 are bent from the second adjoining edge 201 to touch the bottom of the second cover plate 20. Each of the limiting baffles 28 has an erected portion 281 and a stopping portion 282. The erected portion 281 extends downwards from the bottom of the second cover plate 20, and the stopping portion 282 is bent and extended from the erected portion 281. Accordingly, the upward displacement of the first cover plate 10 and the second cover plate 20 is restricted.

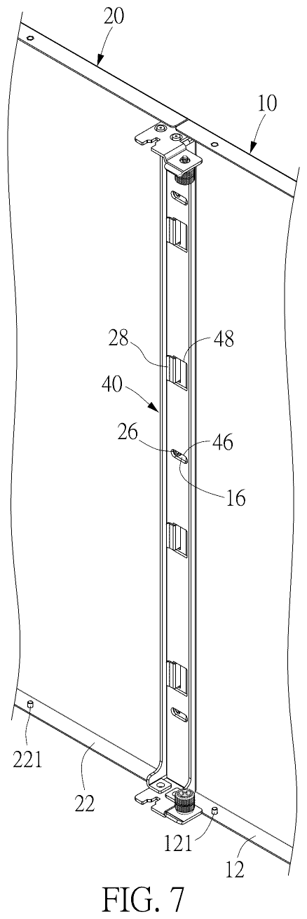

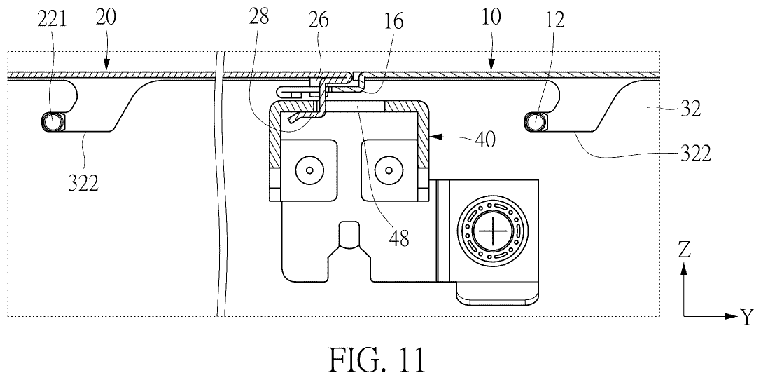

Referring to FIGS. 7 and 11, when the first cover plate 10 is in the locked state, the erected portion 281 passes through the stopping hole 48, and the stopping portion 282 is positioned on a bottom surface of the bridge member 40, thereby restricting the upward displacement of the second cover plate 20 (i.e., in the Z-axis direction in FIG. 11).

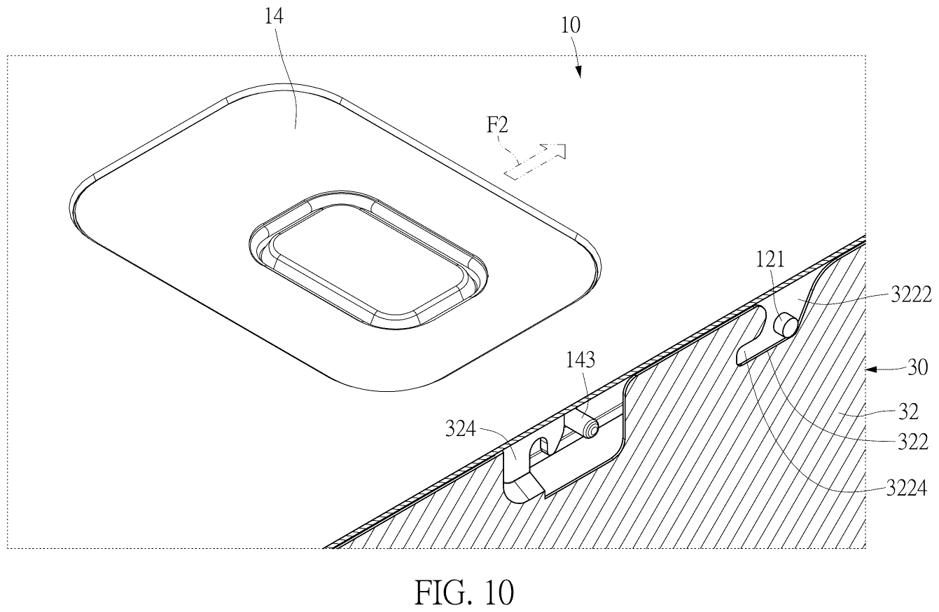

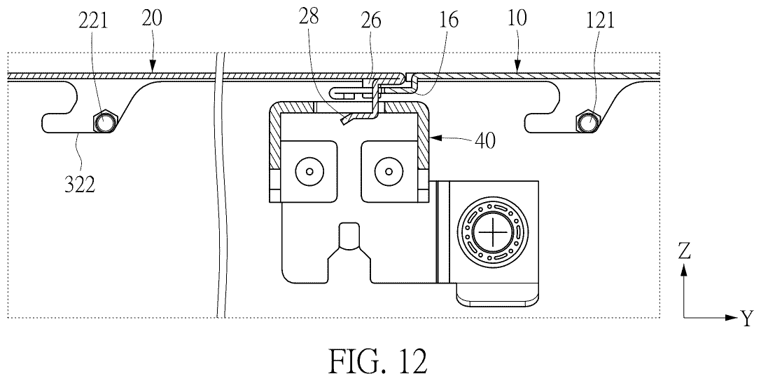

Referring to FIGS. 10 and 12, when the first cover plate 10 is in the unlocked state, the first cover plate 10 is detachable from the case body 30 in a direction away from the second cover plate 20, while simultaneously causing the limiting baffles 28 to disengage from the bridge member 40.

Referring to FIG. 1 to FIG. 3, the first cover plate 10 further includes a plurality of limiting recesses 18 disposed between the first hook members 16. When the first cover plate 10 is in the locked state, the limiting recesses 18 correspondingly restrict the displacement of the erected portions 281 towards the first cover plate 10. In other words, the limiting recesses 18 of the first cover plate 10 are configured to limit the displacement of the limiting baffles 28 of the second cover plate 20 along both the X-axis and Y-axis directions.

### Unlocked State and Unlocking Process

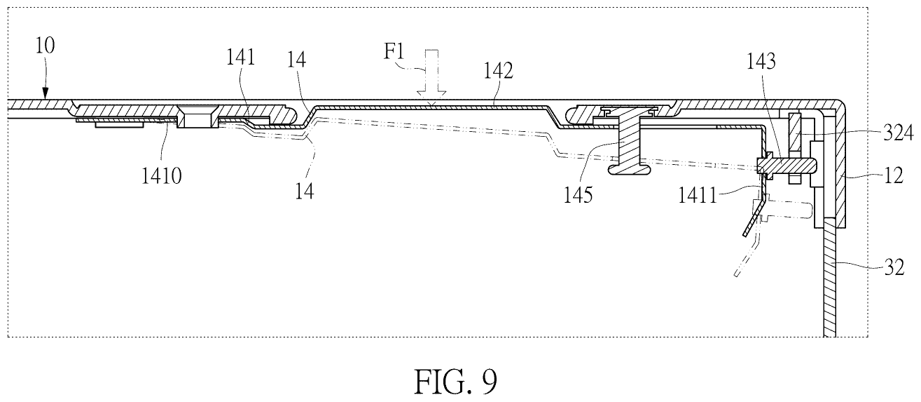

Referring to FIG. 4, the first cover plate 10 includes the two fastening members 14 adjacent to the pair of side plates 32. Referring to FIG. 9, each fastening member 14 includes an elastic arm 141, a movable latch 143, and a pressing portion 142. The elastic arm 141 may be an elongated plate member having elasticity, such as a metal plate, a plastic plate, or a combination thereof. The elastic arm 141 has a fixed end 1410 and a movable end 1411. The movable end 1411 is adjacent to the side plate 32, and the fixed end 1410 is secured to the first cover plate 10 by, for example, riveting. The pressing portion 142 is disposed between the fixed end 1410 and the movable end 1411 and is exposed by a pressing hole 104 on a top surface of the first cover plate 10. The movable latch 143 is connected to the movable end 1411 and extends in a direction perpendicular to the side plate 32. Each side plate 32 has a locking seat 324, and the movable latch 143 is movably engaged with the locking seat 324 of the side plate 32, thereby securing the first cover plate 10 to the case body 30 in the locked state. The movable latch 143 may be engaged with the locking seat 324 of the case body 30 through a pushing-pulling action or a pressing action.

As shown in FIGS. 1 and 10, the locking seat 324 of this embodiment is U-shaped, and can be formed by stamping and bending inwards from the side plate 32. One end of the locking seat 324 is connected to the side plate 32, and the locking seat 324 extends inwards, in parallel to the side plate 32.

As shown in FIGS. 8 to 10, when a user presses the pressing portion 142 in the direction as indicated by an arrow F1, the movable end 1411 moves away from the first cover plate 10 and drives the movable latch 143 away from the locking seat 324 of the side plate 32. As a result, the fastening member 14 is no longer engaged with the locking seat 324, and the first cover plate 10 is thus in the unlocked state relative to the case body 30. At this point, the user can move the first cover plate 10 in the direction away from the second cover plate 20 (as indicated by an arrow F2) to detach the first cover plate 10 from the case body 30. During this process, the elastic arm 141 undergoes elastic deformation, thereby storing a restoring force.

Referring to FIG. 9, each fastening member 14 further includes a limiting rod 145. The limiting rod 145 is fixed to a bottom surface of the first cover plate 10 and is located between the pressing portion 142 and the movable end 1411. In this embodiment, the limiting rod 145 is actually I-shaped and passes through the elastic arm 141. A bottom end of the limiting rod 145 restricts a downward displacement range of the elastic arm 141, so as to prevent the elastic arm 141 from being pressed downwards too much by the user.

As shown in the unlocked state of FIG. 12, when the first cover plate 10 and the case body 30 are in the unlocked state, the first cover plate 10 can move away from the case body 30 in the direction away from the second cover plate 20 while the first hook members 16 is simultaneously driven to disengage from the second hook members 26, so that the second cover plate 20 is movable relative to the case body 30.

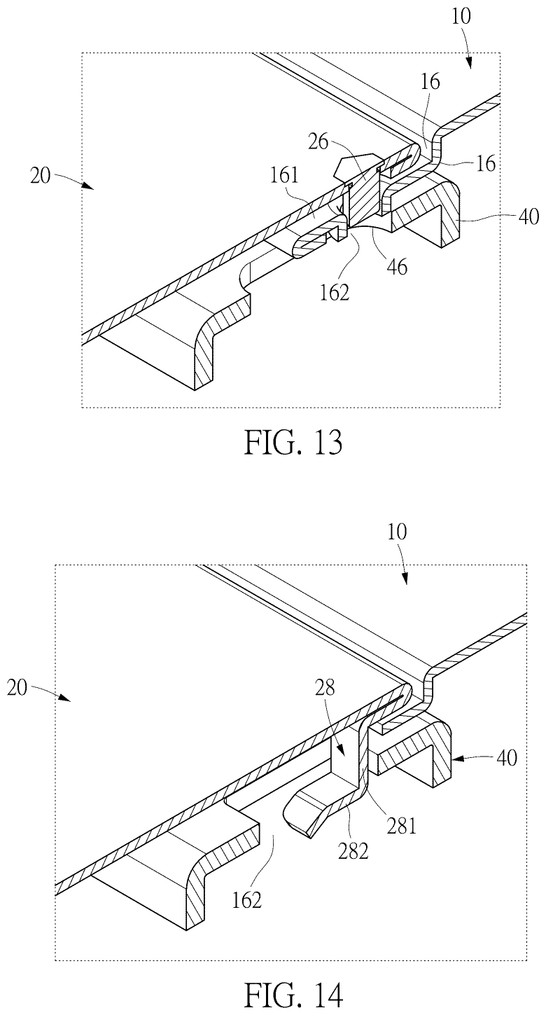

FIG. 13 is a schematic perspective cross-sectional view of FIG. 4 in the unlocked state sectioned along the line V-V. FIG. 14 is a schematic perspective cross-sectional view of FIG. 4 in the unlocked state sectioned along line VI-VI. Referring to FIGS. 13 and 14, when the first cover plate 10 moves in the direction away from the second cover plate 20 (i.e., along the Y-axis direction), the first hook members 16 pull the second hook members 26 towards the Y-axis direction for a certain distance. Referring to FIG. 14, the limiting baffles 28 of the second cover plate 20 also move away from the bridge member 40. That is to say, the stopping portion 282 disengages from the bottom surface of the bridge member 40. At this moment, the second cover plate 20 may move upwards, i.e. in the Z-axis direction.

Additionally, during the unlocking process of the first cover plate 10 moving in the direction away from the second cover plate 20, one end of the first cover plate 10 away from the second cover plate 20 may be lifted, thereby causing the first cover plate 10 to tilt relative to the second cover plate 20. The first hook members 16 may be in an inclined state, such that the second hook members 26 can be free from the constraint of the first hook members 16.

Accordingly, during the unlocking process of the first cover plate 10, the force on the second cover plate 20 is removed, thereby allowing the second cover plate 20 to be moved away from the case body 30.

However, the aforementioned details are disclosed for exemplary purposes only, and are not meant to limit the scope of the present disclosure.

### Beneficial Effects of the Embodiment

In conclusion, when the first cover plate and the case body of the electronic device casing are in the locked state, the displacement of the second cover plate relative to the case body is restricted by the second hook member that is engaged with the first hook member. As a result, the second cover plate does not need the fastening member, thereby not taking up the space below the second cover plate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic device casing, comprising:
a case body having a pair of side plates;
a first cover plate configured to be assembled to the case body, wherein the first cover plate comprises at least one fastening member and at least one first hook member, the at least one first hook member is located on one side of the first cover plate, and the at least one fastening member is movably engaged with at least one of the side plates of the case body, so that the first cover plate and the case body are in a locked state or an unlocked state; and
a second cover plate configured to be assembled to the case body, wherein the second cover plate is adjacent to the first cover plate, the first cover plate and the second cover plate jointly cover the case body, and the second cover plate comprises at least one second hook member;
wherein, when the first cover plate and the case body are in the locked state, the at least one second hook member is engaged with the at least one first hook member to restrict displacement of the second cover plate relative to the case body;
wherein, when the first cover plate and the case body are in the unlocked state, the first cover plate is detachable from the case body in a direction away from the second cover plate, and the at least one first hook member is simultaneously driven to disengage from the at least one second hook member, so that the second cover plate is movable relative to the case body.

2. The electronic device casing according to claim 1, wherein the first cover plate comprises two fastening members adjacent to the pair of side plates, each of the fastening member has a movable latch, and each of the side plates has a locking seat; and the movable latch is movably engaged with the locking seat, so that the first cover plate and the case body are in the locked state.

3. The electronic device casing according to claim 2, wherein each of the fastening members comprises an elastic arm and a pressing portion, the elastic arm has a fixed end and a movable end, the fixed end is fixed to the first cover plate, the movable end is adjacent to the side plate, the movable latch is connected to the movable end and extends in a direction perpendicular to the side plate, and the pressing portion is disposed between the fixed end and the movable end and is exposed on a top surface of the first cover plate.

4. The electronic device casing according to claim 3, wherein each of the fastening members further comprises a limiting rod, the limiting rod is fixed to a bottom surface of the first cover plate and is located between the pressing portion and the movable end, and the limiting rod restricts a downward displacement range of the elastic arm.

5. The electronic device casing according to claim 2, wherein the locking seat is U-shaped and formed by stamping and bending inwards from the side plate, one end of the locking seat is connected to the side plate, and the locking seat extends inwards and is parallel to the side plate.

6. The electronic device casing according to claim 1, wherein each of the side plates has a plurality of hook grooves, and each of the plurality of hook grooves extends downwards from a top edge of the side plate and is horizontally bent in a direction from the first cover plate toward the second cover plate; and wherein a plurality of first sliders are disposed on and protrude from each of two sides of the first cover plate, a plurality of second sliders are disposed on and protrude from each of two sides of the second cover plate, and the plurality of first sliders and the plurality of second sliders are correspondingly and slidably engaged with the plurality of hook grooves, so as to restrict upward displacement of the first cover plate and the second cover plate.

7. The electronic device casing according to claim 1, further comprising a bridge member, wherein two ends of the bridge member are fixed to the pair of side plates, and the bridge member is located below an adjoining area of the first cover plate and the second cover plate.

8. The electronic device casing according to claim 7, wherein the first cover plate comprises a first adjoining edge, a quantity of the at least one first hook member of the first cover plate is plural, each of the first hook members comprises an engagement plate and a limiting aperture, the engagement plate is bent downwards from the first adjoining edge and extends to a bottom of the second cover plate, and the limiting aperture is formed on the engagement plate; wherein the second cover plate comprises a second adjoining edge, a quantity of the at least one second hook member of the second cover plate is plural, and each of the second hook members has a columnar shape and is fixed to a bottom surface of the second cover plate; and when the first cover plate is in the locked state, the first adjoining edge abuts the second adjoining edge, and the second hook members are inserted into the limiting apertures.

9. The electronic device casing according to claim 8, wherein the bridge member has a plurality of stopping holes, the second cover plate further comprises a plurality of limiting baffles, the plurality of limiting baffles are bent from the second adjoining edge to the bottom of the second cover plate, each of the plurality of limiting baffles has an erected portion and a stopping portion, the erected portion extends downwards from the bottom of the second cover plate, and the stopping portion is bent and extends from the erected portion; wherein, when the first cover plate is in the locked state, the erected portion passes through the stopping hole, and the stopping portion is located on a bottom surface of the bridge member, so as to restrict upward displacement of the second cover plate; and wherein, when the first cover plate is in the unlocked state, the first cover plate is detachable from the case body in the direction away from the second cover plate, and the plurality of limiting baffles are simultaneously driven to disengage from the bridge member.

10. The electronic device casing according to claim 9, wherein the first cover plate further has a plurality of limiting recesses; and wherein, when the first cover plate is in the locked state, the plurality of limiting recesses correspondingly restrict displacement of the erected portions toward the first cover plate.
